(19) United States
(12) Patent Application Publication
(10) Pub. No.: US 2003/0030108 A1
(43) Pub. Date: Feb. 13, 2003

(54) Thin film transistor and method for manufacturing the same

(75) Inventor: Narihiro Morosawa, Ishikawa (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma (JP)

(21) Appl. No.: 10/159,247

(22) Filed: May 29, 2002

(30) Foreign Application Priority Data
May 30, 2001 (JP) 2001-163060

(51) Int. Cl. H01L 23/62

(52) U.S. Cl. 257/359

(57) ABSTRACT

The invention provides a method for carrying out a heat treatment required during the manufacture of a thin film transistor (TFT) at relatively low temperatures. In this method, in a heating step in which at least a portion of a silicon-based semiconductor layer is crystallized, a silicide is formed in a source region and a drain region in the semiconductor layer. A TFT according to the invention includes a silicon-based semiconductor layer having a channel region, a source region and a drain region being so disposed as to sandwich the channel region, a source electrode electrically connected to the source region, a drain electrode electrically connected to the drain region, and a gate electrode insulated from the source electrode and the drain electrode, and the source region and the drain region contains a silicide.

### FIELD OF THE INVENTION

This invention relates to thin film transistors and methods for manufacturing same. The invention also relates to array substrates and image display devices employing the thin film transistors, such as active matrix liquid crystal display devices and active matrix organic electroluminescent (EL) display devices.

### BACKGROUND OF THE INVENTION

Conventionally, thin film transistors (TFTs) that use polycrystalline silicon (polysilicon) for the semiconductor layers have been used widely for pixel switching elements in liquid crystal display devices or the like.

A typical configuration of a polysilicon TFT is shown in FIG. 14. In this TFT, an undercoat layer 82 is formed on a glass substrate 81, and at a predetermined position on the surface of the undercoat layer, a polysilicon semiconductor layer 83 is formed. The semiconductor layer 83 includes a channel region 84, a source region 85, and a drain region 86, the source region 85 and the drain region 86 being disposed so as to sandwich the channel region 84. Between the channel region 84 and the source region 85 and between the channel region 84 and the drain region 86, LDD (lightly-doped drain) regions 87a and 87b are interposed respectively. The polysilicon semiconductor layer 83 is, except for contact holes, covered with a gate insulating layer 88, and a gate electrode 89 is disposed on the gate insulating layer 88 above the channel region. The source region 85 and the drain region 86 respectively are connected to a source electrode 91a and a drain electrode 91b, which are connected to the respective regions via contact holes. An interlayer insulating film 90 and a passivation film 93 are formed, for example, to provide electrical insulation between the respective electrodes as well as to the structure thereabove.

Referring to FIGS. 15 and 16, a manufacturing method of the thin film transistor having the above configuration is described below.

(a) First, amorphous silicon is deposited on the surface of an undercoat layer 82 formed on a substrate 81 to form an amorphous silicon layer (a-Si layer) 100 (FIG. 16A).

(b) Next, the a-Si layer 100 is irradiated with laser light to melt and crystallize (to laser anneal) the layer and is patterned using photolithography and etching to form a patch of (isolated) polysilicon layer (p-Si layer) 101 (FIG. 16B).

(c) Subsequently, a gate insulating layer 88 is formed covering the patch of the p-Si layer 101 (FIG. 16C).

(d) Then, a gate electrode 89 is formed on the gate insulating layer 88 above the region which later forms the channel region (FIG. 16D).

(e) Next, using the gate electrode 89 as a mask, doping is performed at a low dose of impurity ions (for example, phosphorus ions) from above the substrate (first doping), and thereby, low-concentration impurity regions are formed in regions of the p-Si layer 101 outside the region directly below the gate electrode 89. These low-concentration impurity regions serve as n⁻ regions 102a and 102b, and the region directly below the gate electrode 89 serves as a channel region 84 (FIG. 16E).

(f) Subsequently, a resist mask 30 with openings in the regions that correspond to the source region and the drain region is formed, and doping is performed at a high dose of impurity ions (for example, phosphorus ions) from above (second doping). Thus, LDD regions 87a and 87b having a low impurity concentration are formed on both sides of the channel region 84 of the p-Si layer, and a source region 85 and a drain region 86 having a high impurity concentration are formed further to the outside (FIG. 16F).

(g) Then, the resist mask is removed, and a heat treatment is carried out, for example, for one hour at a high temperature of about 600° C. Thus, crystal defects in the source region 85 and the drain region 86 that have been caused by the impurity ion implantation are restored (crystallized) and the impurity ions are activated (FIG. 16G).

(h) Next, an interlayer insulating layer 90 is formed covering the gate electrode 89 (FIG. 16H).

(i) Subsequently, contact holes 103a and 103b are formed piercing through the interlayer insulating layer 90 and the gate insulating layer 88 (FIG. 16I).

(j) Then, a metal is filled into the contact holes 103 to form a source electrode 91a and a drain electrode 91b, and a passivation film 93 is formed so as to cover these electrodes (FIG. 16J).

Thus, a thin film transistor (TFT) employing polysilicon is obtained. This TFT employs polysilicon containing a large quantity of large-sized crystal grains for the semiconductor layer and therefore exhibits a high electron mobility of 10 to several hundred cm²/Vs.

In this TFT, a heat treatment at a high temperature of about 600° C. or more is required to crystallize (activate) the semiconductor layer after the impurity ion implantation. When such a high temperature heat treatment is performed, the impurity ions that have been implanted into the source region, the drain region, and LDD regions tend to diffuse into the channel region, causing large variations in the drive characteristics among the fabricated TFTs.

The variations in drive characteristics become more noticeable as TFTs are miniaturized. Therefore, the variations can cause serious problems in image display devices in which a large number of miniature-sized TFTs are arranged on a single substrate.

### SUMMARY OF THE INVENTION

The present inventors have found that the crystallization temperature can be reduced when a silicide is formed in a silicon-based semiconductor layer during a heat treatment for the layer, and thus, have accomplished the present invention.

A TFT according to the present invention includes: a silicon-based semiconductor layer having a channel region, a source region, and a drain region, the source region and the drain region being disposed so as to sandwich the channel region; a source electrode electrically connected to the source region; a drain electrode electrically connected to the drain region; and a gate electrode insulated from the source electrode and the drain electrode. The TFT is characterized in that the source region and the drain region contain a silicide.

The present invention also provides a method for manufacturing the TFT. The manufacturing method includes the steps of: forming a silicon-based semiconductor layer, implanting impurity ions into at least regions of the silicon-based semiconductor layer that are to be formed into the source region and the drain region, and heating the silicon-based semiconductor layer to crystallize at least a portion of the silicon-based semiconductor layer. The method is characterized in that a silicide is formed in the source region and the drain region in the silicon-based semiconductor layer by the heating during the heating step.

When a silicide is formed in a layer in the heating step, the silicide serves as crystal seeds while crystallization proceeds. Therefore, crystallization of the silicon-based semiconductor layer and, for example, restoration of crystal defects, can be performed at a lower temperature than has conventionally been required. Hence, TFTs can be fabricated that have smaller variations in drive characteristics than conventional TFTs.

In the present specification, the term “silicon-based semiconductor layer” is intended to mean a semiconductor layer containing silicon, especially a semiconductor layer in which the total amount of silicon and germanium, which is a congener of silicon, is 50 atomic % (at %) or more.

### BRIEF DESCRIPTION OF THE DRAWINGS

FIG. 1 is a flow chart illustrating an example of a manufacturing method for a thin film transistor (TFT) according to the present invention.

FIGS. 2A to 2L are cross-sectional views illustrating the manufacturing method shown in FIG. 1 in more detail.

FIGS. 3A to 3C are cross-sectional views illustrating a modified example of the manufacturing method shown in FIGS. 1 and 2;

FIGS. 4A to 4H are cross-sectional views illustrating another modified example of the manufacturing method shown in FIGS. 1 and 2.

FIG. 5 is a flow chart illustrating further another modified example of the manufacturing method shown in FIGS. 1 and 2.

FIG. 6 is a graph showing the relationship between heat treatment temperature for and ON current in a TFT.

FIGS. 7A to 7D are cross-sectional views illustrating yet another modified example of the manufacturing method shown in FIGS. 1 and 2.

FIGS. 8A to 8C are cross-sectional views illustrating still another modified example of the manufacturing method shown in FIGS. 1 and 2.

FIG. 9 is a graph showing the relationship between thickness of the channel region and current value of a TFT.

FIG. 10 is a graph showing the relationship between thickness of the source region and the drain region and current value of the TFT.

FIG. 11 is a cross-sectional view showing an example of a TFT according to the present invention.

FIG. 12 is a cross-sectional view showing another example of a TFT according to the present invention.

FIG. 13 is a cross-sectional view showing yet another example of a TFT according to the present invention.

FIG. 14 is a cross-sectional view of a conventional TFT.

FIG. 15 is a flow chart showing an example of a conventional manufacturing method for a TFT.

FIGS. 16A to 16J are cross-sectional views illustrating the conventional method shown in FIG. 15 in more detail.

FIG. 17 shows a wiring pattern in one example of a liquid crystal display device employing a TFT of the present invention.

FIG. 18 shows a wiring pattern in one example of an organic EL display device employing a TFT of the present invention.

### DESCRIPTION OF THE PREFERRED EMBODIMENTS

Preferred embodiments of the TFT according to the present invention are discussed below.

The silicon-based semiconductor layer may be of polycrystalline silicon (polysilicon) or may contain silicon and germanium. When the latter is the case, it is preferable that the source region and the drain region contain silicon and germanium and the channel region is a silicon layer. Introducing germanium reduces the band gap of the source region and the drain region.

It is desirable that the concentration of germanium (Ge) in the source region and the drain region is from 1 at % to 80 at %. If the concentration of Ge is less than 1 at %, the effects achieved by adding Ge are not sufficient, whereas if the concentration of Ge is greater than 80 at %, defects in the source region and so forth increase considerably, which might significantly degrade the TFT characteristics significantly. A more preferable range of the concentration of Ge is from 20 at % to 60 at %.

It is preferable that the semiconductor layer containing silicon and germanium is a silicon germanium layer, or more specifically, a polycrystalline silicon germanium layer.

It is preferable that a silicide is formed at least in the source region at the interface with the source electrode and in the drain region at the interface with the drain electrode. When a silicide is formed at the interfaces to these electrodes, the contact resistances between the semiconductor layer and the source and drain electrodes are reduced. The reduction in the contact resistances is effective in increasing the ON currents. In this case, it is preferable that a silicide is not formed at any interfaces except at the interface of the source region to the source electrode and at the interface of the drain region to the drain electrode. The purpose of this is to prevent the OFF current from increasing. In order to suppress the OFF current, it is preferable that a silicide is not formed in the portions of the source region and the drain region that are in contact with the channel region (or the LDD regions). In particular, when both the source region and the drain region contain silicon and germanium, the resistance value becomes lower than that of the silicon layer, and therefore, more careful consideration of the portions in which a silicide is to be formed is necessary.

It is preferable that the channel region includes, when taken along the thickness direction of the silicon-based semiconductor layer, a portion that is thinner than any portions of the source region and the drain region that contain a silicide. According to this preferable example, an increase in the OFF current caused by the formation of a silicide is suppressed. In addition, it is preferable that, when taken along the thickness direction of the silicon-based semiconductor layer, the thickness of the portions of the source region and the drain region that comprise a silicide is 100 nm or greater, and the channel region includes a portion having a thickness of from 40 nm to 70 nm. According to this preferable example, a TFT that exhibits a sufficiently high ON current and a sufficiently low OFF current is achieved easily.

The silicon-based semiconductor layer further may include regions, for example LDD regions, having an impurity concentration higher than that of the channel region but lower than that of the source region and the drain region, those regions provided between the channel region and the source region and between the channel region and the drain region.

On side faces of the gate electrode, insulative sidewalls may be formed. These side walls preferably are disposed so as to be in contact with at least a pair of opposing side faces of the gate electrode. These sidewalls are effective in reducing the OFF current. Therefore, when devices are miniaturized, for example, when the distance between a pair of the opposing side faces that are in contact with the side walls is, for example, 2 μm or less, particularly when it is 1 μm or less, it is preferable that the sidewalls are formed as described above. The thickness of the sidewalls, when taking the side faces of the gate electrode as their bottom faces, (the thickness measured in the in-plane direction of the silicon semiconductor layer) may be preferably 1 μm or less, for example, 0.3-0.5 μm.

In the heating process, it is preferable that the silicon-based semiconductor layer is heated to not more than 450° C. When the heating temperature is not more than 450° C., unannealed glasses or glass substrates having low glass transition temperatures (for example, 500° C. or lower) can be used as the substrate; therefore, inexpensive products can be provided easily. It should be noted that the lower limit of the heating temperature is not particularly limited, but a temperature of 350° C. or higher is desirable in terms of the orientation of crystallization.

For the reason stated above, it is preferable in a manufacturing method according to the present invention that when taken along a thickness direction of the silicon-based semiconductor layer, the channel region includes a portion that is thinner than any portions of the source region and the drain region that comprise the silicide. In addition, the method further may include a step of forming an insulative side wall on a side face of the gate electrode.

In a manufacturing method of the present invention, it is preferable that prior to the step of heating, a step of forming a metal layer contacting the silicon-based semiconductor layer is performed, and in the step of heating, a silicide is formed from a metal contained in the metal layer and silicon contained in the silicon-based semiconductor layer. In this case, it is preferable that prior to the step of forming a metal layer, a step of forming an insulating layer (a mask) covering a portion of the silicon-based semiconductor layer further is provided, and in the step of forming a metal layer, the metal layer is formed so that the metal layer is in contact with the surface of the silicon-based semiconductor layer that is not covered with the insulating layer. The purpose of this is to form a silicide at predetermined positions. In addition, using the mask, a source (or a drain) electrode may be formed so as to be in contact with the same region where the metal layer has been formed.

In a manufacturing method according to the present invention, prior to the step of heating, a step of implanting metal ions into the silicon-based semiconductor layer may be provided so that a silicide is formed from the metal ions and the silicon contained in the silicon-based semiconductor layer.

The silicon-based semiconductor layer is formed on a substrate. The layer is not necessarily formed directly on the substrate, but may be formed on an undercoat layer formed over the substrate.

Preferably, an amorphous layer that is formed and then crystallized is used for the silicon-based semiconductor layer. It is preferable that the crystallization is performed by, for example, laser annealing before the step of heating, for example, prior to the step of implanting impurity ions. When impurity ions are implanted after the crystallization, crystal defects are produced in at least a portion of the silicon-based semiconductor layer (the layer becomes amorphous). In this case, the crystal defects in the source region and the drain region are restored (crystallized) in the step of heating.

The silicon-based semiconductor layer may be formed into an amorphous layer, and the crystallization of the amorphous layer may be performed in the step of heating. In this case, the crystallization of the whole amorphous layer and the formation of a silicide proceed in the same heating step. In the case that the crystallization of the whole amorphous layer and the formation of the silicide are performed at the same time, the heating may be performed by laser light irradiation. In the present invention, there is no particular limitation to the means for heating used in the step of heating.

In one embodiment of the present invention, the following steps are performed: forming a silicon-based semiconductor layer on a substrate; implanting impurity ions into regions of the silicon-based semiconductor layer that correspond to the source region and the drain region; forming a metal layer on at least a portion of the surfaces of the regions of the silicon-based semiconductor layer that correspond to the source region and the drain region; and heating the silicon-based semiconductor layer having the impurity ions implanted therein and being in contact with the metal layer to crystallize the silicon-based semiconductor layer and to form a silicide by reacting a metal contained in the metal layer and the silicon in the semiconductor layer.

With this method, the metal diffuses from the metal layer to the silicon-based semiconductor and reacts with silicon, thus forming a silicide. Then, the formed silicide serves as crystal seeds, and crystal growth takes place. As a consequence, crystal defects in the silicon-based semiconductor layer can be restored even at lower temperatures than were conventionally required. Moreover, since a silicide is formed in the vicinity of the surface layer of the source region and the drain region, the contact resistance tends to be reduced.

In the method described above, the implantation of impurity ions may be performed either before or after the formation of the metal layer.

In another embodiment of the present invention, the following steps are performed: forming a silicon-based semiconductor layer on a substrate; implanting impurity ions in regions that correspond to the source region and the drain region in this layer; implanting metal ions in regions that correspond to the source region and the drain region in the layer; and heating the silicon-based semiconductor layer in which the impurity ions and the metal ions have been implanted to crystallize the semiconductor layer and to form a silicide by reacting the metal ions and the silicon in the semiconductor layer.

In this method as well, a silicide is formed in the silicon-based semiconductor layer and the formed silicide serves as crystal seeds, and therefore, the crystallization can be performed at lower temperatures than were conventionally required. In this method, if the metal ion implantation energy is controlled, the metal ions can be implanted into the source region and the drain region at a desired depth and at a desired concentration. Thus, control of the crystallization is facilitated.

In this method as well, the implantation of impurity ions may be performed either before or after the formation of the metal layer. In addition, impurity ions and metal ions may be implanted at the same time.

In yet another embodiment of the present invention, the following steps are performed: forming a metal layer on at least a portion of regions on a substrate that correspond to a source region and a drain region; forming a silicon-based semiconductor layer so as to cover the metal layer; implanting impurity ions into regions silicon-based semiconductor layer that correspond to the source region and the drain region; and heating the silicon-based semiconductor layer in which the impurity ions have been implanted to crystallize the semiconductor layer and to form a silicide by reacting the metal contained in the metal layer and the silicon in the semiconductor layer.

In this method as well, a silicide is formed in the layer and crystal growth takes place with the formed silicide serving as crystal seeds, and therefore, the crystallization can be performed at lower temperatures than were conventionally required. This method is advantageous in that miniature-sized TFTs can be fabricated with high precision because the metal layer with a small area is formed in advance.

In yet another embodiment of the present invention, in the step of forming a silicon-based semiconductor layer, the silicon-based semiconductor layer is formed so that a region that is to be formed into the channel region is thinner than at least a portion of each of the regions that forms the source region and the drain region. Then, a silicide is formed in at least the above-described portion of the source region or the drain region. With this method, the OFF current due to silicide is easily suppressed.

Thus, in a TFT of the present invention, it is preferable that a silicide is disposed so as not to be in contact with the channel region. Accordingly, in each of the embodiments described above, it is preferable that the metal layer is formed in a region that is not in contact with the channel region, or the metal ions are implanted in a region that is not in contact with the channel region.

There is no particular limitation to the method for forming a silicon-based semiconductor layer that has a film thickness difference, and it is possible to form, for example, a thin film in advance and then to form another film only on the regions of this layer that later form a source region and a drain region. Alternatively, it is also possible to form, for example, a thick layer in advance, and then to remove a portion of the formed film from a region of the layer except for the regions that later form a source region and a drain region.

In still another embodiment of the present invention, a step of implanting germanium ions into regions of the silicon-based semiconductor layer that later form a source region and a drain region further may be provided. With this method, a TFT can be fabricated in which the source region and the drain region are silicon germanium layers and the channel region is a silicon layer.

The TFTs according to the present invention may be applied to the following devices. Each of the image display devices illustrated below includes an array substrate in which TFTs of the present invention are disposed on the substrate.

Liquid Crystal Display Device

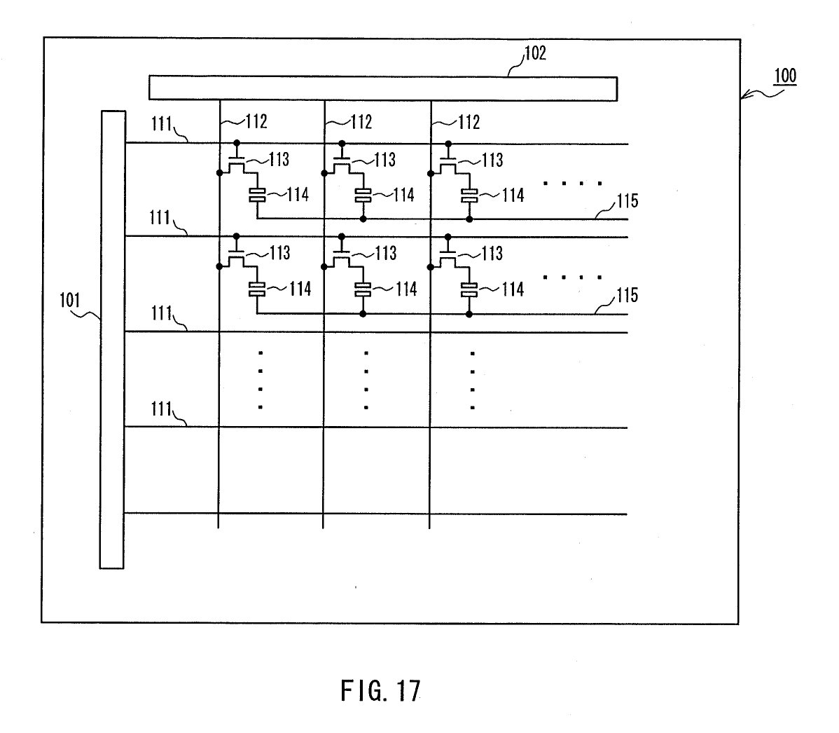

In an active matrix liquid crystal display device 100 shown in FIG. 17, each of switching transistors 113 arranged in a matrix configuration drives a liquid crystal 114 that corresponds to the transistor. The switching transistors 113 respectively are connected to gate lines 111, data lines 112, and ground lines 115. The gate lines 111 are connected to a gate line driver circuit 101 and the data lines 112 are connected to a data line driver circuit 102. When the switching transistors 113 are TFTs according to the present invention, good display characteristics are achieved.

Organic EL Display Device

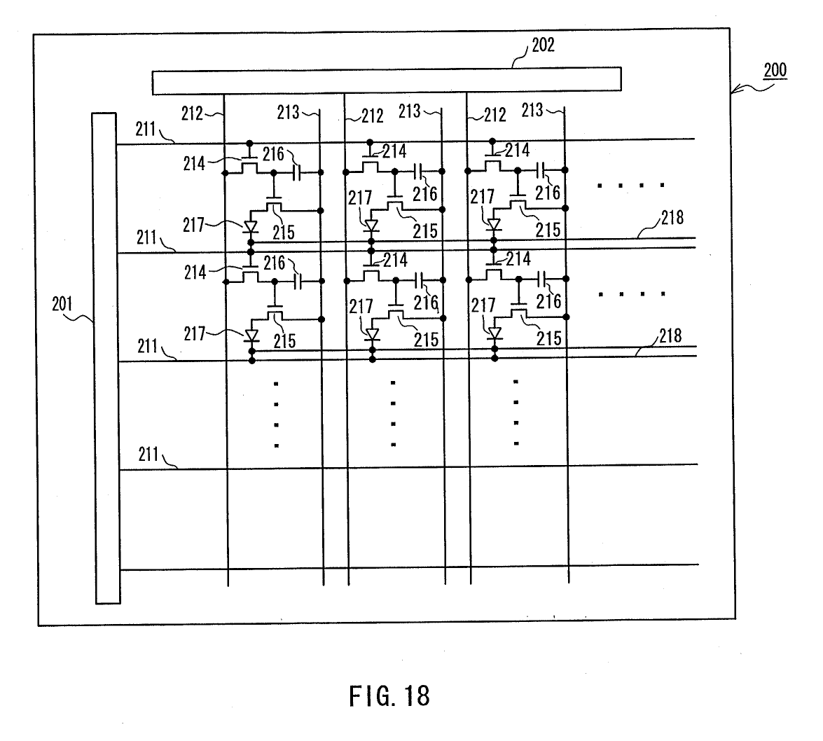

In an organic EL display device 200 shown in FIG. 18, switching transistors 214 and storage transistors 215 arranged in a matrix configuration drive organic EL elements 217 that correspond to these transistors. The switching transistors 214 respectively are connected to gate lines 211 and data lines 212, and also are connected to power source lines 213 via storage capacitor elements 216. The storage transistors 215 are connected to the switching transistors 214, the power source lines 213, and the organic EL elements 217. The organic EL elements 217 also are connected to ground lines 218. The gate lines 211 are connected to a gate line driver circuit 201, and the data lines 212 are connected to a data driver circuit 202. When the switching transistors 214 and the storage transistors 215 are TFTs according to the present invention, good display characteristics are achieved.

Preferred embodiments of the present invention are discussed further below referring to the drawings and taking top-gated thin film transistors (with a gate length of 1 μm) having LDD regions as examples.

Embodiment 1

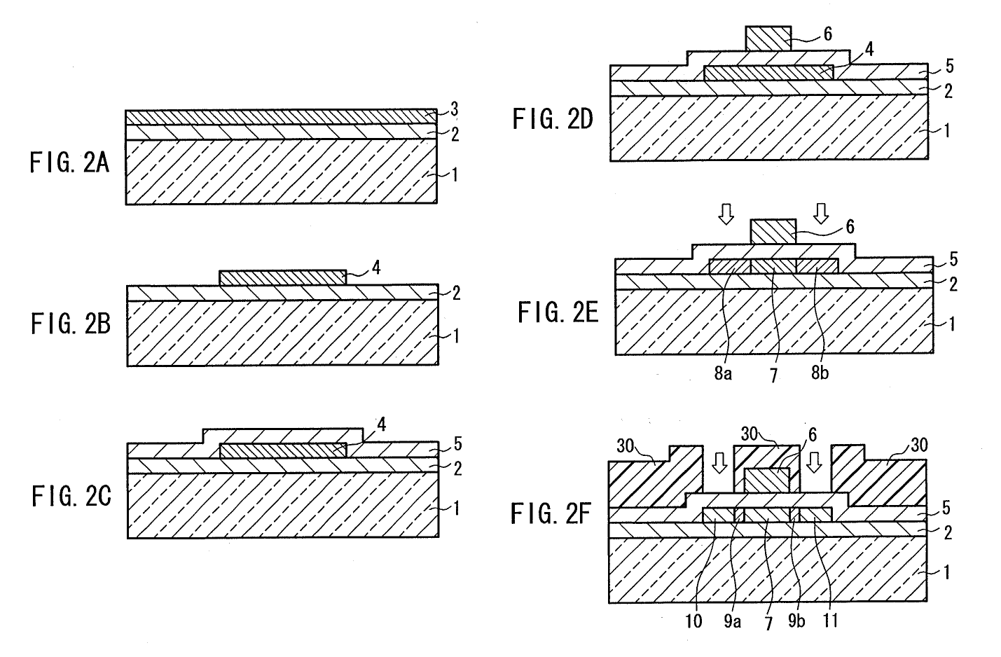

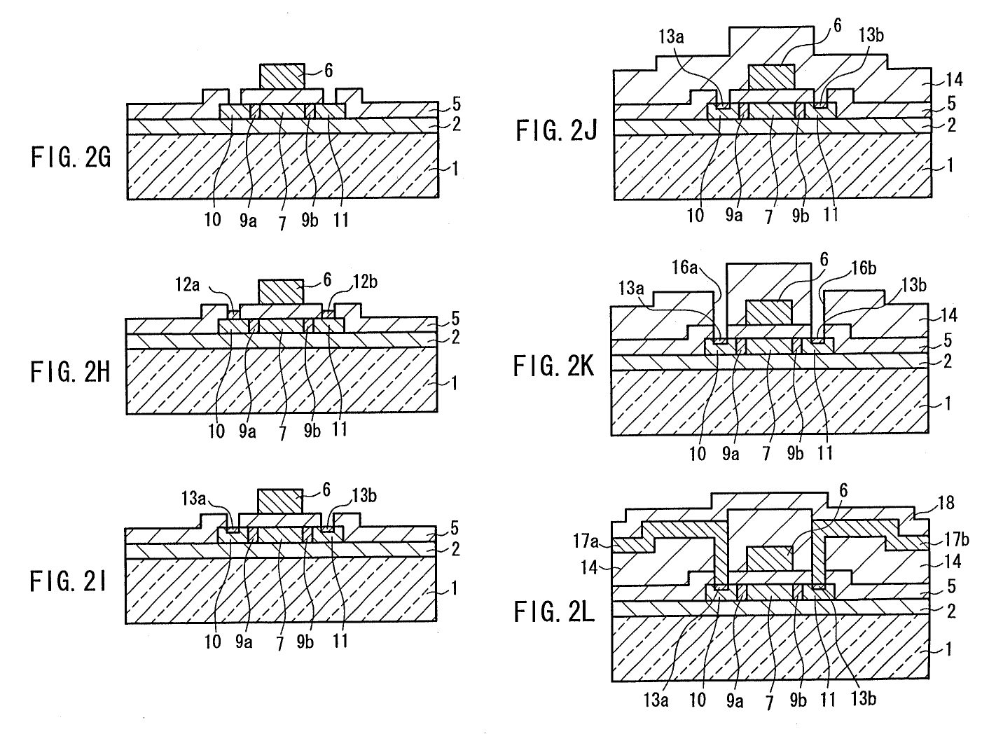

(a1) First, an amorphous silicon layer (a-Si layer) 3 having a thickness of 50 nm is formed on a SiO₂ layer (undercoat layer) 2 on a glass substrate 1 by plasma CVD or reduced-pressure CVD, and a dehydrogenation treatment is carried out in a nitrogen atmosphere at a temperature of 450° C. (FIG. 2A).

(b1) Next, the a-Si layer 3 is melted and crystallized (turned into polysilicon) by laser annealing using an excimer laser with XeCl, KrF, or the like as an excited gas, and thereafter, a patch-shaped polysilicon layer (p-Si layer) 4 is formed at a predetermined position by photolithography and etching (FIG. 2B).

(c1) Subsequently, a SiO₂ layer having a thickness of 100 μm, serving as a gate insulating layer 5, is formed so as to cover the p-Si layer 4 (FIG. 2C).

(d1) Then, a MoW alloy is formed into a film having a thickness of about 400-500 nm, for example, by a sputtering process, and a MoW alloy layer, serving as a gate electrode 6, is formed by photolithography and etching (FIG. 2D). It should be noted that, in place of the MoW alloy, a layered structure of Ta and a MoW alloy, for example, may be used for the gate electrode.

(e1) Next, using the gate electrode 6 as a mask, a first impurity doping is carried out. For example, phosphorus ions are implanted at a dose of 5×10¹²/cm². Thus, the portion directly below the gate electrode 6 is made into a channel region 7, which is not doped with impurities, and the portions excluding the channel region 7 are made into n⁻ regions 8a and 8b, which are doped with impurities (FIG. 2E).

(f1) Subsequently, a resist mask 30 with openings that correspond to the surfaces of the regions which later form the source region and the drain region is formed, and a second impurity doping is carried out. For example, phosphorus ions are implanted at a dose of 1×10¹⁴/cm². Thus, the regions that have been doped with impurity ions at the first impurity doping but not at the second impurity doping are regions having a low impurity concentration (n⁻ regions; LDD regions 9a and 9b), whereas the regions that have been doped with impurities in both the first impurity doping and the second impurity doping are regions having a high impurity concentration (n⁺ regions; a source region 10 and a drain region 11) (FIG. 2F).

(g1) Then, after the resist mask is removed, the gate insulating layer 5 above the source region 10 and the drain region 11 is etched to expose portions of the surfaces of the source region 10 and the drain region 11 (FIG. 2G). The portions to be etched are preferably the same portions as the openings of the contact holes which will be described later, that is, the contact portions of the source electrode and the drain electrode.

(h1) Next, in the portions that have been opened by etching, titanium films 12a and 12b having a thickness of about 20 nm are formed by, for example, a sputtering process (FIG. 2H). It should be noted that, in place of the titanium film, it is also possible to use a metal layer of, for example, cobalt or nickel.

(i1) Subsequently, a heat treatment is performed, for example, at 450° C. for about one hour. Thus, the titanium in the titanium film diffuses into the source region and the drain region. From the diffused titanium and silicon, a metal silicide (titanium silicide) is formed, and with the formed titanium silicide serving as crystal seeds, the semiconductor layer that has become amorphous by the impurity ion doping is crystallized.

Thereafter, the metal layer (titanium film) that has not been reacted is removed with an acid (for example, a heated sulfuric acid) having a temperature of about 120° C. Thus, portions containing a metal silicide (silicide portions) 13a and 13b are formed in the vicinity of the surfaces of the source region 10 and the drain region 11 (FIG. 2I).

It should be noted that, although the silicide portions 13a and 13b are depicted as if they have explicit boundary lines in FIG. 2I, the boundary lines of the silicide portions are not necessarily clear, depending on the degree of the diffusion of the metal (titanium) (this also applies to the following embodiments).

(j1) Then, a silicon oxide film, serving as an interlayer insulating layer 14, is formed so as to cover the gate electrode 6 (FIG. 2J).

(k1) Next, contact holes 16a and 16b are formed through the interlayer insulating layer 14 (thickness of 300 nm) and the gate insulating layer 5 (FIG. 2K).

(l1) Subsequently, a titanium/aluminum film (thickness: 80 nm/4000 nm), serving as the source electrode 17a and the drain electrode 17b is formed, and further, a silicon nitride film (thickness: 500 nm) serving as a passivation film 18, is formed (FIG. 2L). Thereafter, a heat treatment is performed in a hydrogen atmosphere or a nitrogen atmosphere at about 350° C. for about one hour. Thus, hydrogen is introduced into the polysilicon and the interface between the polysilicon and the gate insulating layer. Thus, a TFT in which the source region and the drain region contain a silicide is obtained.

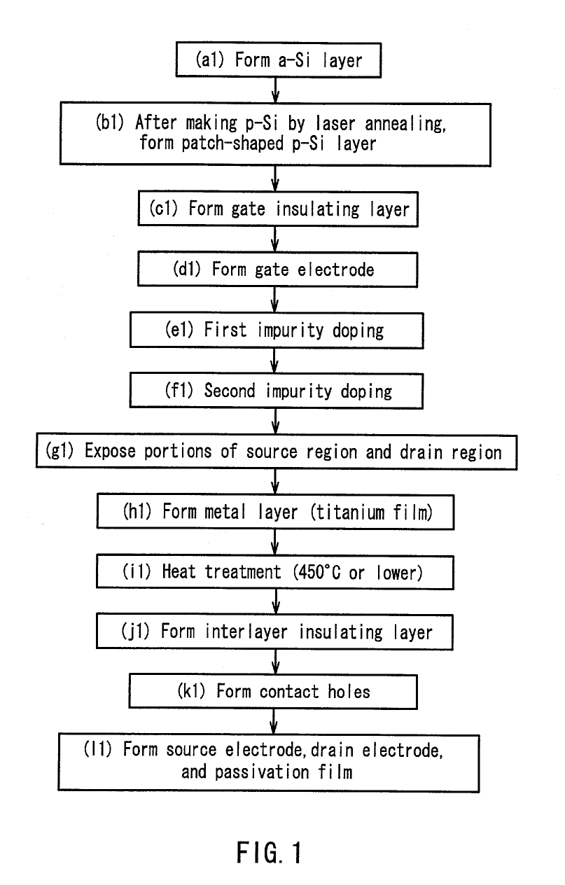

A summary of the above-described steps (a1) to (l1) is given in FIG. 1.

The TFT obtained through the above-described steps contains a silicide in the source (or drain) region that is in contact with the source (or drain) electrode and therefore exhibits a low contact resistance and a high ON current. Moreover, since the crystallization is carried out while a silicide is being formed, the temperature of the heat treatment can be lowered. Furthermore, LDD regions are provided to prevent the occurrence of hot carriers, thereby increasing reliability.

It should be noted that the sequence of the steps is not limited to that described above. For example, it has been described that a metal layer (a titanium film) is formed after the second impurity doping, but it is also possible to form the metal layer prior to the second doping. When doping is performed after the metal layer is formed, the metal contained in the metal layer (titanium) and the silicon efficiently mix with each other, and the uniformity of the titanium silicide portions is thus improved.

Embodiment 2

In the present embodiment, first, the steps (a1) to (e1) are performed in a similar manner to Embodiment 1 (see FIGS. 1 and 2).

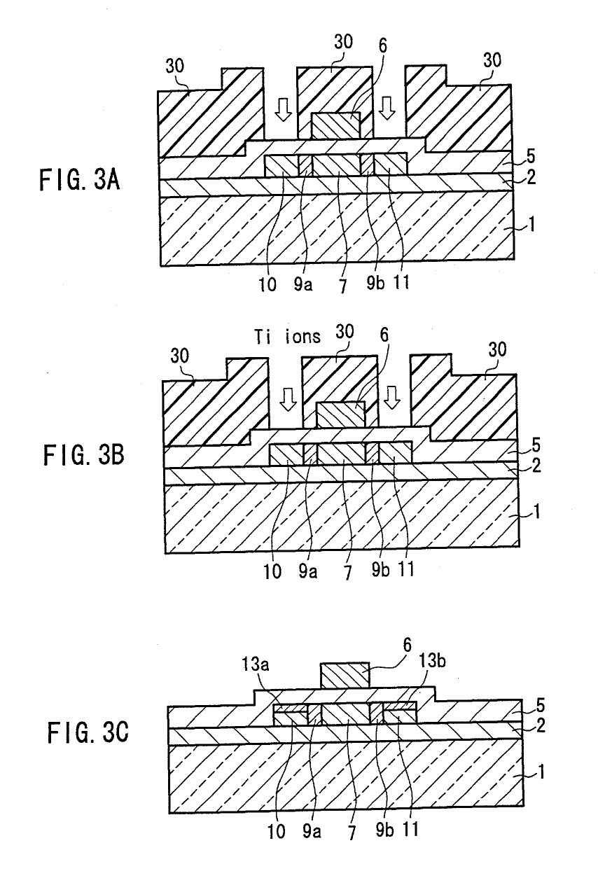

(f2) Next, a resist mask 30 is formed to have openings that correspond to the surfaces of the regions which later form the source region and the drain region, and a second impurity doping is performed. The resist mask 30 is formed so as to cover the gate electrode 6. The doping may be carried out by, for example, implanting phosphorus ions at a dose of 1×10¹⁴/cm². Thus, as well as a channel region 7, LDD regions 9a and 9b, a source region 10, and a drain region 11 are formed (FIG. 3A).

(g2) Subsequently, without removing the resist mask 30, metal ions (titanium ions) are implanted. By implanting titanium ions in this manner, titanium ions are implanted in the same regions as the regions in which impurity ions have been introduced in the second doping (the regions that later form the source region and the drain region). It should be noted that in place of titanium ions, ions of other metals such as cobalt or nickel may be used (FIG. 3B).

(h2) Then, the resist mask 30 is removed, and a heat treatment is carried out, for example, at about 450° C. for about one hour. Thus, silicon and titanium ions react with each other in the source region 10 and in the drain region 11, forming titanium silicide portions 13a and 13b, and the semiconductor layer that has become amorphous by the impurity ion doping is crystallized (FIG. 3C).

Thereafter, the steps (j1) to (l1) as in Embodiment 1 are carried out (see FIGS. 1 and 2). Thus, a TFT in which the source region and the drain region contain a silicide is obtained.

In the present embodiment, it is not necessary to expose the source (or drain) region for the purpose of forming a metal layer or to remove unnecessary portions of the metal layer, and therefore, the manufacturing process is simplified. In addition, by controlling the metal ion implantation energy, metal ions can be implanted into the source (or drain) region at a desired depth and at a desired concentration, and consequently, control of the crystallization can be facilitated.

In this embodiment as well, metal ions may be implanted prior to the second implantation of impurity ions. Alternatively, the second implantation of impurity ions and the implantation of metal ions may be carried out at the same time. When they are implanted simultaneously, an advantage is attained in that production efficiency is increased.

Embodiment 3

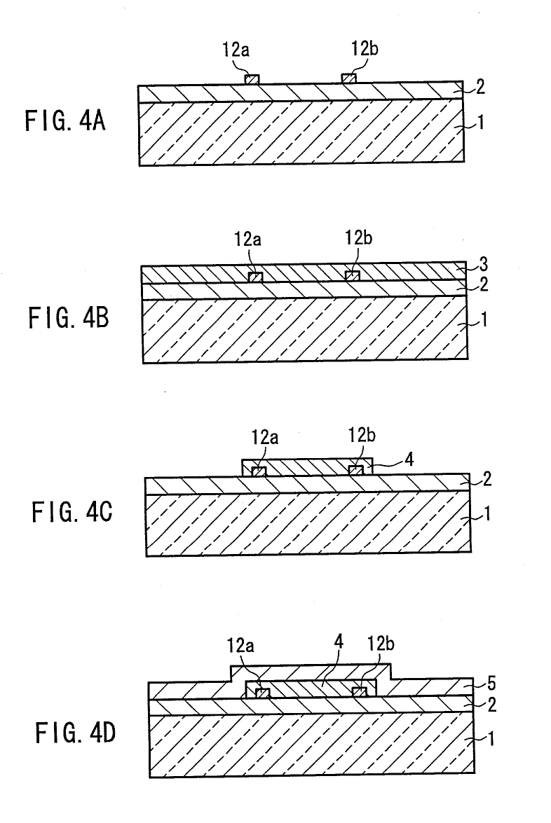

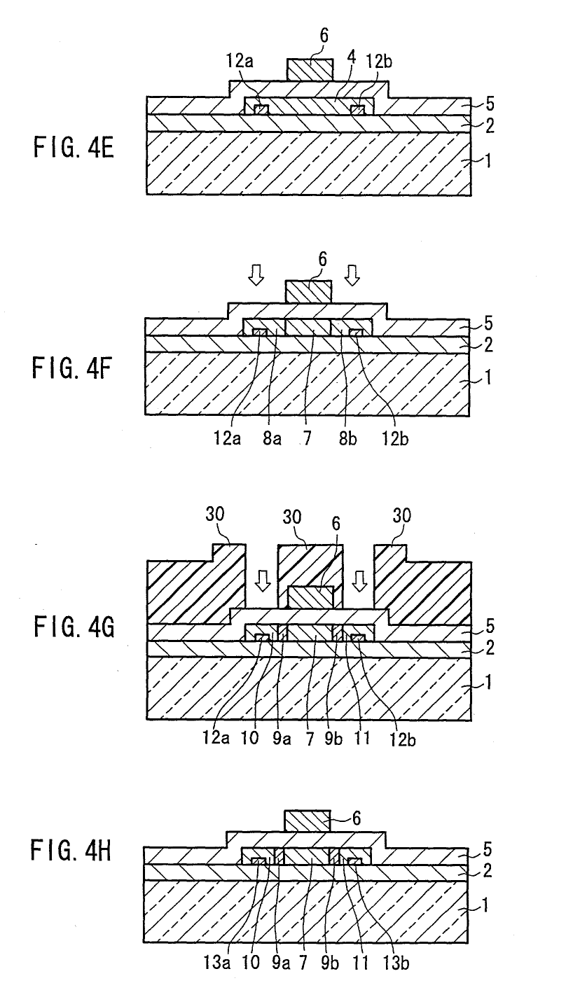

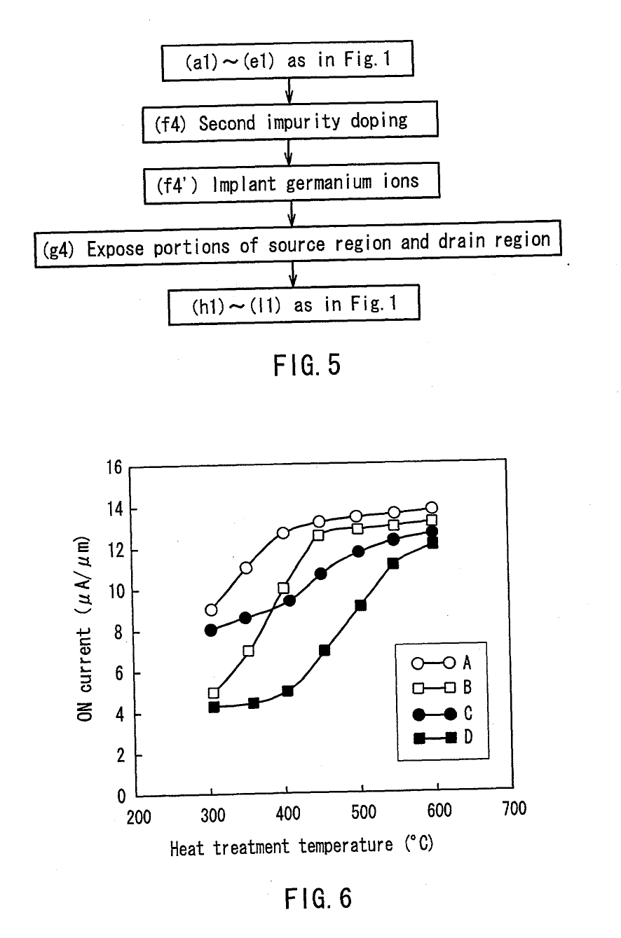

(a3) First, on a SiO₂ layer (undercoat layer) 2 formed on a glass substrate 1, patches of a metal layer (a titanium film) 12a and 12b having a thickness of 20 nm are formed by a sputtering process at positions that correspond to the source region and the drain region that are to be formed in a later step. Also in this step, in place of the titanium film, it is possible to use a layer of other metals such as cobalt or nickel (FIG. 4A).

(b3) Next, on the metal layer (titanium film) 12, an amorphous silicon layer (a-Si layer) 3 is formed to a thickness of 50 nm by plasma CVD or reduced-pressure CVD, and a dehydrogenation treatment is carried out in a nitrogen atmosphere at 450° C. (FIG. 4B).

(c3) Subsequently, the a-Si layer 3 is melted and crystallized (turned into polysilicon) by laser annealing using an excimer laser employing XeCl, KrF, or the like as the excited gas, and thereafter, a patch-shaped p-Si layer 4 is formed by photolithography and etching (FIG. 4C).

(d3) Then, a SiO₂ film having a thickness of 100 nm, serving as a gate insulating layer 5, is formed covering the p-Si layer 4 (FIG. 4D).

(e3) Next, a MoW alloy film is formed to a thickness of about 400-500 nm by, for example, a sputtering process, and then, a gate electrode 6 is formed by photolithography and etching (FIG. 4E). It should be noted that, in place of the MoW alloy, a layered structure of Ta and a MoW alloy, for example, may be used for the gate electrode.

(f3) Subsequently, using the gate electrode 6 as a mask, a first impurity doping is carried out. The doping may be carried out by, for example, implanting phosphorus ions at a dose of 5×10¹²/cm². Thus, a channel region 7, which is directly below the gate electrode 6, is a region that is not doped with impurities, whereas the portions outside the channel region are n⁻ regions 8a and 8b, which are doped with impurities (FIG. 4F).

(g3) Then, a resist mask 30 with openings that correspond to the regions which later form the source region and the drain region is formed, and a second impurity doping is carried out. The doping may be carried out by, for example, implanting phosphorus ions at a dose of 1×10¹⁴/cm². Thus, the regions that have been doped with the impurity ions in the first impurity doping but not in the second impurity doping become regions having a low impurity concentration (LDD regions) 9a and 9b. The regions that have been doped with an impurity in both the first impurity doping and the second impurity doping become regions having a high impurity concentration (n⁺ regions; source region 10 and drain region 11 (FIG. 4G).

(h3) Next, after removing the resist mask, a heat treatment is carried out at a temperature of 450° C. for one hour. Thus, silicon and titanium react with each other in the source region 10 and the drain region 11, forming titanium silicide portions 13a and 13b (FIG. 4H).

Then, the steps (j1) to (l1) as in Embodiment 1 are carried out (see FIGS. 1 and 2). Thus, a TFT in which the source region and the drain region contain a silicide is obtained.

In the present embodiment, the metal layer is formed in advance by patterning, and therefore, an advantage is attained in that the invention can be applied easily to miniature-sized TFTs.

Embodiment 4

In the present embodiment, first, the steps (a1) to (e1) as in Embodiment 1 are performed, as shown in FIG. 5 (see FIGS. 1 and 2).

(f4) Next, a resist mask is formed to have openings that correspond to the regions which later form the source region and the drain region, and a second impurity doping is carried out. The doping may be carried out by, for example, implanting phosphorus ions at a dose of 1×10¹⁴/cm². Thus, LDD regions and the regions that form the source region and the drain region are separated.

(f4′) Subsequently, without removing the resist mask, germanium ions are implanted at a dose of, for example, 1×10¹⁵/cm² in the same positions that have been subjected to the second impurity doping. Thus, germanium ions are implanted into the regions that form the source region and the drain region, and as a consequence, the source region and the drain region are formed of polycrystalline silicon germanium.

Thereafter, the steps (g1) to (l1) as in Embodiment 1 are performed (see FIGS. 1 and 2). Thus, a TFT in which the source region and the drain region are formed of polycrystalline silicon germanium and contain a silicide is obtained.

In the present embodiment, the source region and the drain region are formed of polycrystalline silicon germanium, which has a smaller band gap than that of polysilicon, and therefore, the carriers that are accumulated below the channel are removed easily. Accordingly, a TFT having a high electron mobility is provided.

In the present embodiment also, the sequence of the steps is not limited to that described above. For example, it is also possible to implant germanium ions prior to the second implantation of impurity ions. Furthermore, germanium ions also may be implanted after a titanium film has been formed. When the second impurity ion implanting and the germanium ion implanting are carried out after the formation of the titanium film, titanium and silicon efficiently mix with each other, and the titanium silicide portions are easily provided with a uniform quality. Moreover, for example, germanium ions may be implanted at the same time as the second implantation of impurity ions.

In addition, germanium ions may be implanted also into the regions that correspond to the LDD regions. If this is the case, germanium ions may be implanted, for example, after the first implantation of impurity ions.

In the steps described above, a metal layer is used to form a silicide, but the present embodiment is not limited thereto and, for example, the implantation of metal ions as described in Embodiment 2 may be adopted.

FIG. 6 shows the relationship between heating treatment temperatures and ON currents in the TFTs made in accordance with the above-described embodiment (Embodiment 4). Here, a comparison was made between TFTs in which a silicide is formed during a heat treatment and TFTs that are heat-treated without producing a silicide.

Sample A is a TFT in which the source region and the drain region contain a silicide and are formed of polycrystalline silicon germanium (the Ge concentration being 40 at %). Sample B is a TFT in which the source region and the drain region contain a silicide and are formed of polycrystalline silicon. By contrast, sample C is a TFT in which the source region and the drain region do not contain a silicide and are formed of polycrystalline silicon germanium (the Ge concentration being 40 at %). Sample D is a TFT in which the source region and the drain region do not contain a silicide and are formed of polycrystalline silicon. It can be seen from the comparisons between samples A and C and between samples B and D in FIG. 6 that, by forming a silicide, heating treatment temperatures required for obtaining desired ON currents can be reduced.

Embodiment 5

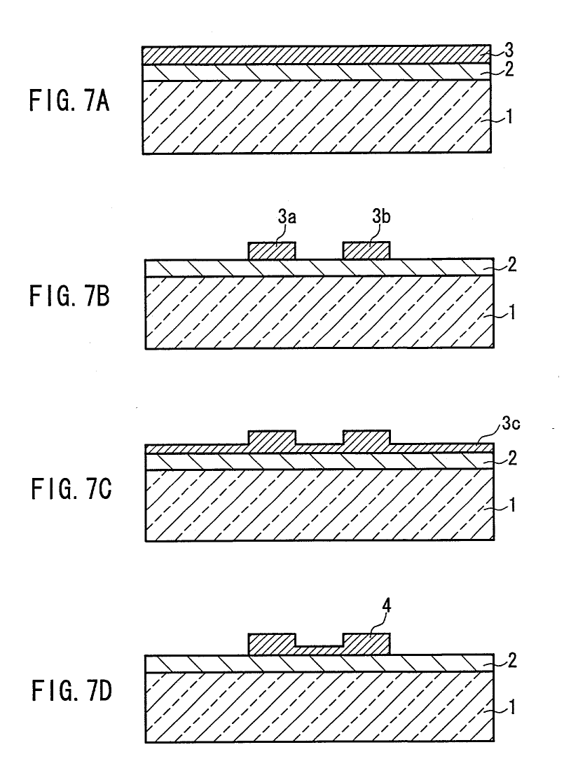

(a5) First, an a-Si layer 3 having a thickness of 100 nm is formed over a SiO₂ layer (undercoat layer) 2 on a glass substrate 1 by plasma CVD or reduced-pressure CVD (FIG. 7A).

(b5) Next, the a-Si layer 3 is subjected to photolithography and etching to remove it except for regions 3a and 3b that correspond to the source region and the drain region (FIG. 7B).

(b5′) Subsequently, a native oxide film on the surface of the a-Si layer 3a and 3b is removed by etching using a dilute hydrofluoric acid, and thereafter, an a-Si layer 3c having a thickness of about 50 nm is immediately formed by plasma CVD. Then, this layer is subjected to dehydrogenation at 450° C. in a nitrogen atmosphere. The thickness of the a-Si layer is such that the regions 3a and 3b that correspond to the source region and the drain region are thick (thickness of 150 nm) whereas the other portions are thin (thickness of 50 nm) (FIG. 7C).

(b5″) Then, the a-Si layer 3 is melted and crystallized (turned into polycrystal) by laser annealing using an excimer laser employing XeCl, KrF, or the like as the excited gas, and thereafter, a patch-shaped p-Si layer 4 is formed by photolithography and etching. This patch-shaped p-Si layer 4 has a relatively large thickness in the portions that later form the source region and the drain region but a relatively small thickness in the region that connects the source region and the drain region (FIG. 7D).

Thereafter, the steps (c1) to (l1) as in Embodiment 1 are performed (see FIGS. 1 and 2). Thus, a TFT is obtained in which a silicide is contained in the source region and the drain region that have an increased thickness.

In the present embodiment, the source region and the drain region have a relatively large thickness, and therefore, a silicide is formed easily in the source region and the drain region in such a manner that a silicide is not present at the junction portions that are connected to a region interposed between the source region and the drain region. When silicide is eliminated from the junction portions, a good junction is realized. Moreover, this configuration prevents a silicide from becoming the source of leakage currents, and consequently, an increase in the OFF current is suppressed.

Embodiment 6

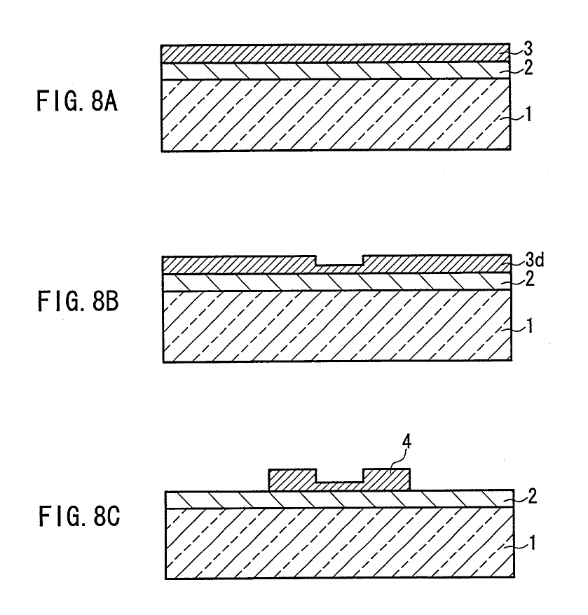

(a6) First, an a-Si layer 3 having a thickness of 150 nm is formed over a SiO₂ layer (undercoat layer) 2 on a glass substrate 1 by plasma CVD or reduced-pressure CVD (FIG. 8A).

(b6) Next, an a-Si layer 3d is formed by photolithography and etching so that the regions that correspond to the channel region and LDD regions (the regions that connect the source region and the drain region) are formed into a thin film having a reduced thickness of about 50 nm (FIG. 8B). Thereafter, a native oxide film on the surface of the formed layer is removed using a dilute hydrofluoric acid, and then a dehydrogenation treatment is performed in a nitrogen atmosphere at a temperature of 450° C.

(b6′) Subsequently, the a-Si layer 3 is melted and crystallized (turned into polysilicon) by laser annealing using an excimer laser employing XeCl, KrF, or the like as an excited gas, and thereafter, a patch-shaped p-Si layer 4 is formed by photolithography and etching. This patch-shaped p-Si layer 4 has a relatively large thickness in the portions that later form the source region and the drain region but a relatively small thickness in the region that connects the source region and the drain region (FIG. 8C).

Thereafter, the steps (c1) to (l1) as in Embodiment 1 are performed (see FIGS. 1 and 2). According to the present embodiment, as well as Embodiment 5, a TFT is obtained that contains a silicide in the source region and drain region, which have an increased thickness. This TFT also has good junctions and an increase of the OFF current is suppressed.

In Embodiments 5 and 6, it has been described that a metal layer is used to form a silicide, but the same effects are obtained in TFTs in which a silicide is formed by implanting metal ions.

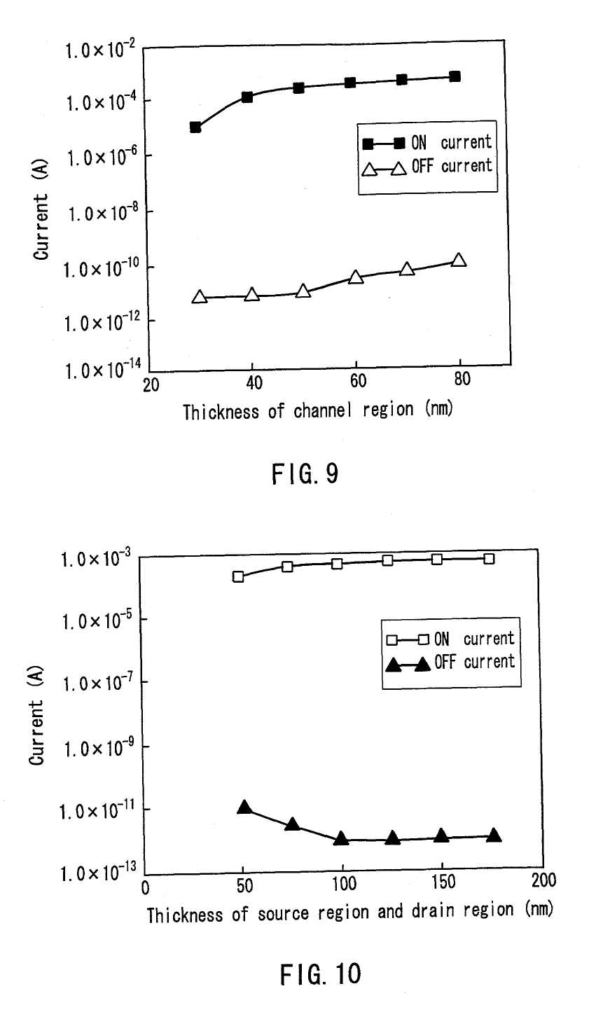

The ON currents and the OFF currents were measured in TFTs in which the thickness of each region in the silicon-based semiconductor layer is controlled according to the present embodiment (Embodiment 6). FIG. 9 shows the relationship between the thickness of the channel region and ON currents and OFF currents when the thickness of the source region and the drain region containing a silicide is constant (100 nm). As shown in FIG. 9, when the thickness of the channel region was from 40 nm to 70 nm, high ON currents and low OFF currents could be achieved at the same time.

FIG. 10 shows the relationship between the thicknesses of the source region and the drain region that contain a silicide and OFF currents and ON currents when the thickness of the channel region (or more precisely, the channel region and the LDD regions) is constant (50 nm). As shown in FIG. 10, when the thickness of the source region and drain region is 100 nm or greater, high ON current and low OFF currents could be achieved at the same time.

It has been confirmed from FIGS. 9 and 10 that when the thickness of the channel region is from 40 nm to 70 nm and the thickness of the source region and drain region containing a silicide is 100 nm or greater, sufficient ON currents and sufficiently low OFF currents are obtained, and thin film transistors having good drive characteristics are achieved.

Embodiment 7

The present embodiment describes an example in which a technique of simultaneously carrying out the formation of a silicide and the crystallization of the a-Si layer is applied to an a-Si layer having varied film thicknesses.

First, an a-Si layer having a thickness of about 100 nm is formed over a SiO₂ layer (undercoat layer) on a glass substrate by plasma CVD or reduced-pressure CVD, and a dehydrogenation treatment is carried out by annealing in a nitrogen atmosphere at about 450° C. Next, a metal layer (a titanium film) having a thickness of about 20 nm is formed by a sputtering process, and the titanium film is patterned so that the film remains in the positions where the source region and the drain region are to be formed. Subsequently, the a-Si layer except the source region and the drain region is dry-etched for about 50 nm to cause a thickness difference in this layer.

Then, the resist film that has been used in the etching is removed, and laser annealing is performed using an excimer layer employing XeCl, KrF, or the like as an exited gas. By this laser annealing, a metal silicide (titanium silicide) is formed in the a-Si layer while the layer is being melted and crystallized.

After this step, a gate insulating film and so forth may be formed, for example, as in the foregoing embodiments (For example, the steps (d3) to (h) in Embodiment 3 and the steps (j1) to (l1) in Embodiment 1 may be performed successively).

It should be noted that when impurity ions are implanted in a subsequent step, the ion-implanted silicon-based semiconductor layer is made amorphous; but the amorphous portion that has become amorphous is recrystallized in a subsequent heating step. In this heating step as well, the silicide functions as crystal seeds, and therefore, the temperature of the heating treatment may be reduced.

When, as in the present embodiment, a laser light is irradiated through a metal layer or is irradiated after titanium ions have been implanted into the surface layer of the semiconductor layer in advance, the laser light irradiation causes the formation of silicide. When the metal layer and the semiconductor layer melted by the laser light irradiation are in contact with each other, a silicide is easily formed.

### EXAMPLE OF FILM STRUCTURE IN THE TFTS

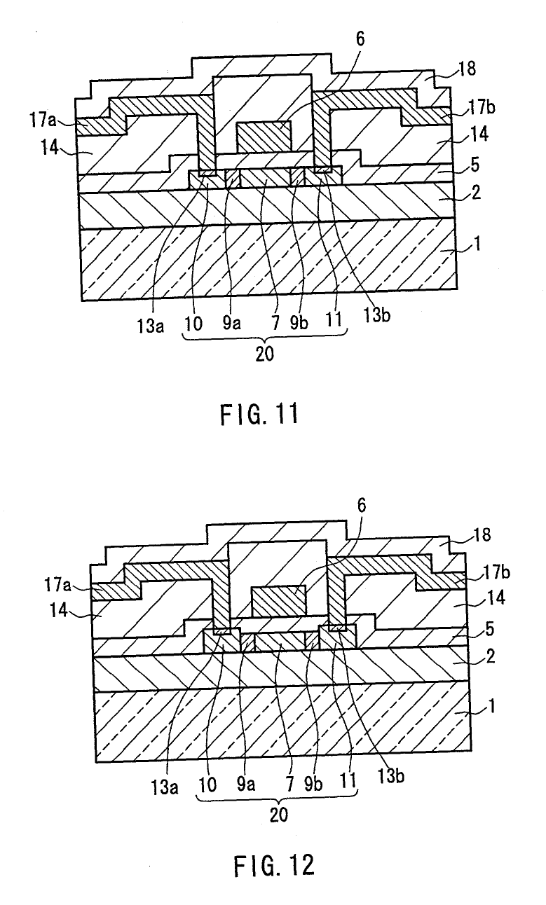

The TFT shown in FIG. 11 can be fabricated according to Embodiments 1 or 2. In Embodiment 2, the depth of the silicide portion may be controlled by controlling the implantation of titanium ions.

In this TFT, a semiconductor layer 20, a gate insulating layer 5, a gate electrode 6, an interlayer insulating layer 14, and a passivation film 18 are layered in this order on the surface of an undercoat layer 2 formed on a glass substrate 1. The semiconductor layer 20 is composed of a channel region 7 positioned directly below the gate electrode 6, a source region (n⁺ region) 10 and a drain region (n⁺ region) 11, which are disposed so as to sandwich the channel region 7 and have a high impurity concentration, and regions 9a and 9b (LDD regions, n⁻ regions) that are disposed between the channel region 7 and the source region 10 as well as between the channel region 7 and the drain region 11 and have a low impurity concentration.

On the surfaces of the source region 10 and the drain region 11, there are silicide portions 13a and 13b, respectively. In this TFT, the silicide portions 13a and 13b are formed so as to be in contact with the source electrode 17a and the drain electrode 17b respectively. A source electrode 17a and a drain electrode 17b respectively are connected to the source region 10 and the drain region 11 via contact holes piercing through the gate insulating layer 5 and the interlayer insulating layer 14.

The TFT shown in FIG. 12 has the same configuration as the TFT shown in FIG. 11 except that the source region 10 and the drain region 11 have a larger thickness than the other regions in the silicon semiconductor layer 20. This TFT can be obtained through the manufacturing method of Embodiment 5 or 6.

Embodiment 8

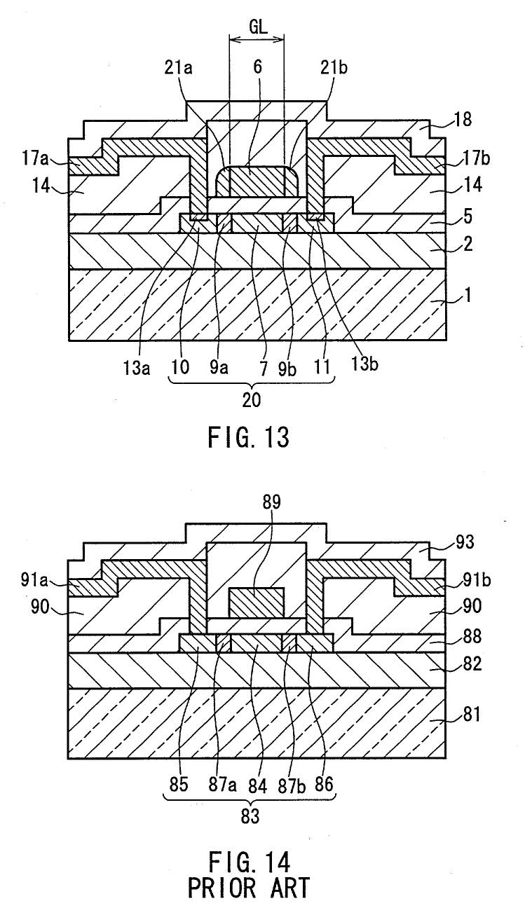

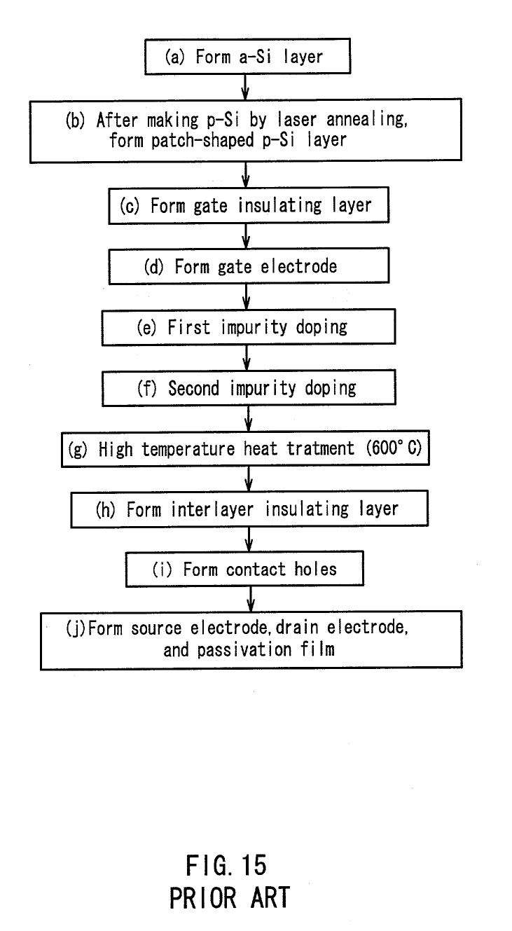

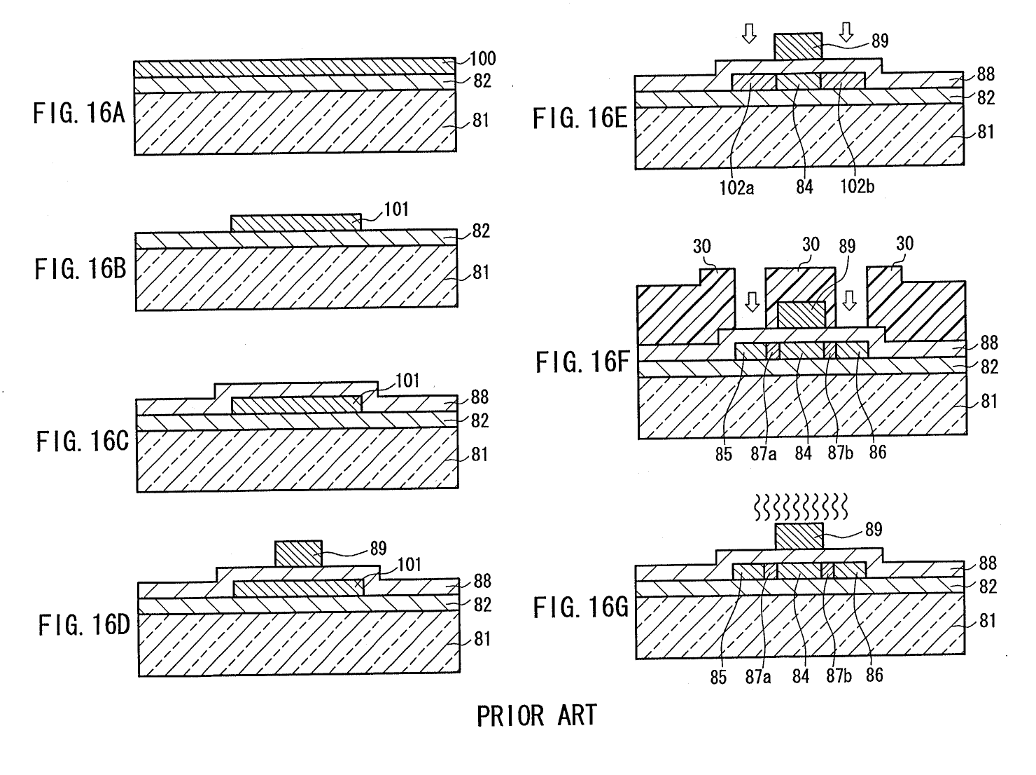

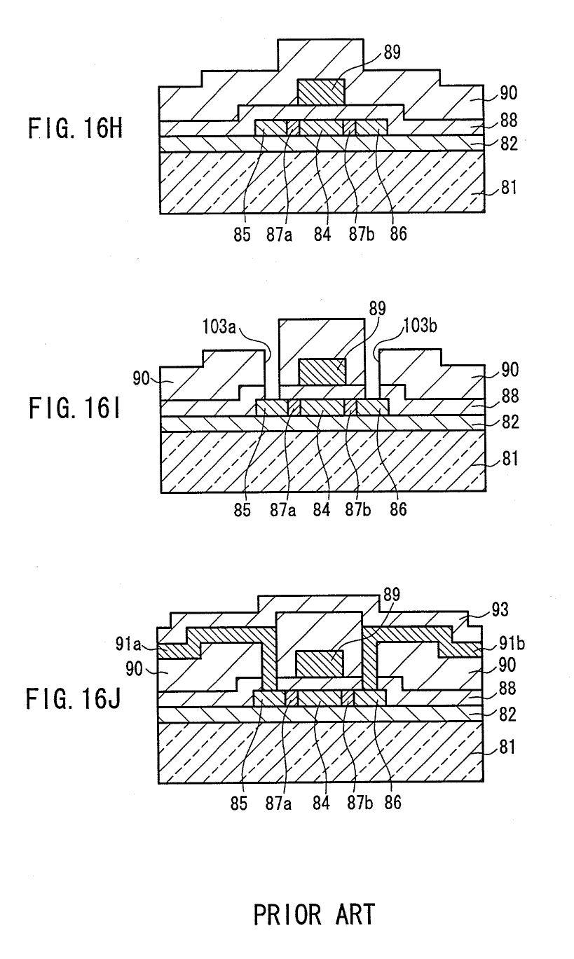

The present embodiment describes a TFT in which insulative sidewalls are disposed on side faces of the gate electrode. When sidewalls 21a and 21b are arranged, as shown in FIG. 13, the insulation performance improves, making it possible to provide a TFT having a small OFF current.

The sidewalls can be formed on side faces of the gate electrode in a self-aligned manner, for example, by, after the first impurity doping, forming a silicon oxide film having a thickness of about 500 nm by plasma CVD and, subsequently, anisotropically etching the silicon oxide film under conditions in which a sufficient selective etching ratio of the silicon oxide film and polycrystalline silicon is ensured.

The sidewalls are not limited to a silicon oxide film but may be a layered film of a silicon oxide film and a silicon nitride film. If this is the case, it is desirable that the silicon oxide film, which adheres well to the gate electrode and the gate insulating film, is positioned, for example, on the side of the gate electrode.

The TFT shown in FIG. 13 can be fabricated in a similar manner to those described in Embodiment 1 and 2 except that the sidewalls are formed.

The sidewalls have the considerable advantageous effect of improving the insulation when the gate length (denoted as GL in FIG. 13) is 2 μm or less.

It should be noted that the present invention is not limited to the embodiments described above, but may be applied to the following TFTs.

(1) In place of top-gated TFTs, bottom-gated TFTs may be employed.

(2) The invention may be applied not only to n-channel TFTs but also to p-channel TFTs that use boron as an impurity.

(3) A region having the same impurity concentration as that of the channel region may be disposed between the channel region and the source region as well as between the channel region and the drain region (LDD regions may be omitted).

(4) For the silicon-based semiconductor layer, polycrystalline silicon germanium carbide may be employed in place of polycrystalline silicon or polycrystalline silicon germanium.

(5) For the gate electrode, polycrystalline silicon germanium may be used. If polycrystalline silicon germanium is used for the gate electrode, it is possible that a p-type gate electrode is used for a p-type TFT and an n-type gate electrode is used for an n-type TFT. Therefore, the threshold voltage can be reduced.

As has been discussed above, according to the present invention, a silicide is formed by a heat treatment to a silicon-based semiconductor layer. This silicide functions as crystal seeds, and therefore, the silicon-based semiconductor layer can be crystallized at lower temperatures than were conventionally required. As a result, variations in drive characteristics are reduced even in miniature-sized TFTs. Hence, by employing such TFTs, inexpensive, small-sized, and light-weight liquid crystal display devices and organic EL display devices can be provided.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A thin film transistor comprising:
a silicon-based semiconductor layer having a channel region, a source region, and a drain region, the source region and the drain region being disposed so as to sandwich the channel region;
a source electrode electrically connected to the source region;
a drain electrode electrically connected to the drain region; and
a gate electrode insulated from the source electrode and the drain electrode;
wherein the source region and the drain region comprise a silicide.

2. The thin film transistor according to claim 1, wherein the silicon-based semiconductor layer comprises silicon and germanium.

3. The thin film transistor according to claim 1, wherein the source region and the drain region comprise silicon and germanium, and the channel region is a silicon layer.

4. The thin film transistor according to claim 3, wherein the concentration of germanium in the source region and the drain region is in the range of 1 at % to 80 at %.

5. The thin film transistor according to claim 1, wherein the silicide is formed at least at an interface of the source region with the source electrode and at an interface of the drain region with the drain electrode.

6. The thin film transistor according to claim 5, wherein, at the interfaces of the source region and the drain region, a silicide is not formed except at the interface of the source region with the source electrode and at the interface of the drain region with the drain electrode.

7. The thin film transistor according to claim 1, wherein when taken along a thickness direction of the silicon-based semiconductor layer, the channel region comprises a portion having a thickness smaller than any portions of the source region and the drain region that comprise the silicide.

8. The thin film transistor according to claim 1, wherein when taken along a thickness direction of the silicon-based semiconductor layer, a thickness of the portions of the source region and the drain region that comprise the silicide are 100 nm or greater, and the channel region comprises a portion having a thickness of from 40 nm to 70 nm.

9. The thin film transistor according to claim 1, wherein the silicon-based semiconductor layer comprises regions having an impurity concentration higher than that of the channel region but lower than that of the source region and the drain region, those regions provided between the channel region and the source region and between the channel region and the drain region.

10. The thin film transistor according to claim 1, further comprising insulative side walls disposed so as to be in contact with at least a pair of opposing side faces of the gate electrode.

11. The thin film transistor according to claim 10, wherein the distance between the side faces contacting the side walls is 2 μm or less.

12. A method for manufacturing a thin film transistor, the thin film transistor comprising:
a silicon-based semiconductor layer having a channel region, a source region, and a drain region, the source region and the drain region being disposed so as to sandwich the channel region;
a source electrode electrically connected to the source region;
a drain electrode electrically connected to the drain region; and
a gate electrode insulated from the source electrode and the drain electrode;
the method comprising the steps of:
forming a silicon-based semiconductor layer;
implanting impurity ions into at least regions of the silicon-based semiconductor layer that are to be formed into the source region and the drain region; and
heating the silicon-based semiconductor layer to crystallize at least a portion of the silicon-based semiconductor layer;
wherein a silicide is formed in the source region and the drain region in the silicon-based semiconductor layer by the heating during the heating step.

13. The method for manufacturing a thin film transistor according to claim 12, wherein, in the heating step, the silicon-based semiconductor layer is heated to 450° C. or lower.

14. The method for manufacturing a thin film transistor according to claim 12, wherein the silicon-based semiconductor layer comprises silicon and germanium.

15. The method for manufacturing a thin film transistor according to claim 12, wherein the silicon-based semiconductor layer is formed so that, when taken a thickness direction of the silicon-based semiconductor layer, the channel region comprises a portion that is thinner than any portions of the source region and the drain region that comprise the silicide.

16. The method for manufacturing a thin film transistor according to claim 12, further comprising a step of forming an insulative side wall on a side face of the gate electrode.

17. The method for manufacturing a thin film transistor according to claim 12, further comprising, prior to the step of heating, a step of forming a metal layer contacting the silicon-based semiconductor layer, wherein in the heating step, a silicide is formed from a metal contained in the metal layer and silicon contained in the silicon-based semiconductor layer.

18. The method for manufacturing a thin film transistor according to claim 17, further comprising, prior to the step of forming a metal layer, a step of forming an insulating layer covering a portion of the silicon-based semiconductor layer, wherein, in the step of forming a metal layer, the metal layer is formed so that the metal layer is in contact with the surface of the silicon-based semiconductor layer that is not covered with the insulating layer.

19. The method for manufacturing a thin film transistor according to claim 12, further comprising, prior to the step of heating, a step of implanting metal ions into the silicon-based semiconductor layer, wherein, in the step of heating, a silicide is formed from the metal ions and silicon contained in the silicon-based semiconductor layer.

20. The method for manufacturing a thin film transistor according to claim 12, further comprising, prior to the step of implanting impurity ions, a step of crystallizing the silicon-based semiconductor layer that has been formed into an amorphous layer, wherein, by implanting the impurity ions, at least a portion of the crystallized silicon-based semiconductor layer in the source region and the drain region is made amorphous.

21. The method for manufacturing a thin film transistor according to claim 12, wherein in the heating step, the silicon-based semiconductor layer that has been formed into an amorphous layer is crystallized.

22. An array substrate comprising the thin film transistor according to claim 1 and a substrate, wherein the thin film transistor is disposed on the substrate.

23. An image display device comprising the thin film transistor according to claim 1 as a pixel switching element.
